(19) United States
(12) Patent Application Publication
(10) Pub. No.: US 2005/0063436 A1
(43) Pub. Date: Mar. 24, 2005

(54) Semiconductor laser module, method of controlling a semiconductor laser beam and video display apparatus

(75) Inventors: Nobuyuki Nishimura, Fukaya-shi (JP); Toshitaka Yamada, Tokyo (JP); Tooru Sugiyama, Kumagaya-shi (JP)

Correspondence Address: PILLSBURY WINTHROP, LLP, P.O. BOX 10500, MCLEAN, VA, 22102, US

(73) Assignee: KABUSHIKI KAISHA TOSHIBA, Tokyo (JP)

(21) Appl. No.: 10/832,459

(22) Filed: Apr. 27, 2004

(30) Foreign Application Priority Data
Apr. 28, 2003 (JP) 2003-123704

(51) Int. Cl. H01S 5/00

(52) U.S. Cl. 372/43; 372/9

(57) ABSTRACT

A semiconductor laser module comprising a semiconductor laser device, a collimating section collimating a laser beam emitted from the semiconductor laser device, a beam shaping section parallel-shifting at least part of a laser beam emitted from the collimating section to a position satisfying an effective numerical aperture of the optical fiber cable when the laser beam exceeds the effective numerical aperture of the optical fiber cable, and a collecting section collecting a laser beam emitted from the beam shaping section onto a light incident end face of the optical fiber cable.

### CROSS-REFERENCE TO RELATED APPLICATIONS

This application is based upon and claims the benefit of priority from the prior Japanese Patent Application No. 2003-123704, filed Apr. 28, 2003, the entire contents of which are incorporated herein by reference.

### BACKGROUND OF THE INVENTION

1. Field of the Invention

The present invention relates to a semiconductor laser module using a high output semiconductor laser device. The present invention relates to a method of controlling a semiconductor laser beam emitted from a high output semiconductor laser device. The present invention relates to a projection type video display apparatus using the semiconductor laser module as light source.

2. Description of the Related Art

As publicly known, there has been recently made technical development for using a semiconductor laser device as a light source in a projection type video display apparatus such as liquid crystal projector.

This kind of video display apparatus takes a laser beam emitted from a semiconductor laser device generating high optical power such as several W to 10 W via optical fiber cable. The laser beam is used to special modulation by a video signal.

In general, the semiconductor laser device has multimode when the power becomes high, and the beam emitting region, that is, the active layer becomes a thin and long shape. More specifically, the direction perpendicular to the active layer, that is, the shorter direction (fast axis direction) of the active layer is several μm. On the other hand, the direction parallel to the active layer, that is, the longer direction (slow axis direction) of the active layer is about 100 μm.

The laser beam emitted from the semiconductor laser device is emitted having the following spread angles. One is a spread angle of several tens of degrees (±10°) in the fast axis direction with respect to the optical axis vertical to the beam emitting region surface. Another is a spread angle of ± several degrees in the slow axis direction with respect to the same as above.

The receiving angle of the optical fiber cable on which the laser beam emitted from the semiconductor laser device is incident is symmetrical with respect to the optical axis vertical to a light incident end face. The receiving angle is about several 10° in both fast and slow axis directions.

Currently, the laser beam emitted from the semiconductor laser device is shaped by an optical system composed of collimator lens and collective lens. By doing so, the laser beam is effectively incident on the optical fiber cable.

In order to adapt the laser beam emitted from the semiconductor laser device to the receiving angle of the optical fiber cable, the laser beam is shaped by the optical system. However, the sine condition (relationship between beam diameter D and spread angle θ, Dsin θ=constant) is given. For this reason, the laser beam incident on the optical fiber cable has a thin and long beam shape having the fast axis direction of several μm and the slow axis direction of several 10 μm.

On the contrary, the shape of the light incident end face of the optical fiber cable is circular in general. In order to enable the entire laser beam having the thin and long beam shape to be incident on the optical fiber cable, the following matter is required. The diameter of the optical fiber cable must be set to the beam diameter of the slow axis direction, that is, several 10 μm.

By doing so, the entire laser beam emitted from the semiconductor laser device is incident on the optical fiber cable. However, the laser beam is incident with considerable margin in the fast axis direction. For this reason, a problem arises such that the optical density (incident light power/cross section of optical fiber cable) of the incident laser beam is reduced. In other words, it is desirable that the cross-sectional shape of the optical fiber cable coincides with the beam shape in order to enable the incidence of laser beam having high light density.

JPN. PAT. APPLN. KOKAI Publications No. 10-300989, 11-316318 and 7-318854 disclose the following technique. According to the technique, the laser beam emitted from the semiconductor laser device is shaped using various lenses in order to enable the incidence of the laser beam with high efficiency and high light density.

However, according to the laser beam shaping technique disclosed in each of the foregoing Publications, the effect adaptable to practical use is not sufficiently obtained. In addition, lenses having special shape must be employed; for this reason, the foregoing laser beam shaping technique is unsuitable for practical use.

### BRIEF SUMMARY OF THE INVENTION

According to one aspect of the present invention, there is provided a semiconductor laser module comprising: a semiconductor laser device; a collimating section collimating a laser beam emitted from the semiconductor laser device; a beam shaping section parallel-shifting at least part of a laser beam emitted from the collimating section to a position satisfying an effective numerical aperture of the optical fiber cable when the laser beam exceeds the effective numerical aperture of the optical fiber cable; and a collecting section collecting a laser beam emitted from the beam shaping section onto a light incident end face of the optical fiber cable.

According to one aspect of the present invention, there is provided a method of controlling a semiconductor laser beam, comprising: collimating a laser beam emitted from the semiconductor laser device; parallel-shifting at least part of the laser beam to a position satisfying an effective numerical aperture of the optical fiber cable when the collimated laser beam exceeds the effective numerical aperture of the optical fiber cable; and collecting the collimated laser beam including the parallel-shifted laser beam onto a light incident end face of the optical fiber cable.

According to one aspect of the present invention, there is provided a video display apparatus comprising: a semiconductor laser module parallel-shifting at least part of a laser beam collimated after being emitted from the semiconductor laser module to a position satisfying an effective numerical aperture of the optical fiber cable when the laser beam exceeds the effective numerical aperture of the optical fiber cable; a modulating section spatially modulating a laser beam outputted from the semiconductor laser module via the optical fiber cable based on a video signal; and a display section projecting and displaying optical output obtained from the modulating section on a screen.

### BRIEF DESCRIPTION OF THE SEVERAL VIEWS OF THE DRAWING

FIG. 1 is a view to explain a liquid crystal projection TV receiver according to one embodiment of the present invention;

FIG. 2A to FIG. 2C are views to explain a semiconductor laser device in the embodiment;

FIG. 3A and FIG. 3B are views to explain the structure of a semiconductor laser module in the embodiment;

FIG. 4A and FIG. 4B are views to explain the structure of a first beam shaping section in the embodiment;

FIG. 5A and FIG. 5B are views to explain the operation of the first beam shaping section in the embodiment;

FIG. 6A and FIG. 6B are views to explain the structure of a second beam shaping section in the embodiment;

FIG. 7A and FIG. 7B are views to explain the operation of the second beam shaping section in the embodiment; and

FIG. 8A and FIG. 8B are views to explain a modification example of the semiconductor laser module according to the embodiment.

### DETAILED DESCRIPTION OF THE INVENTION

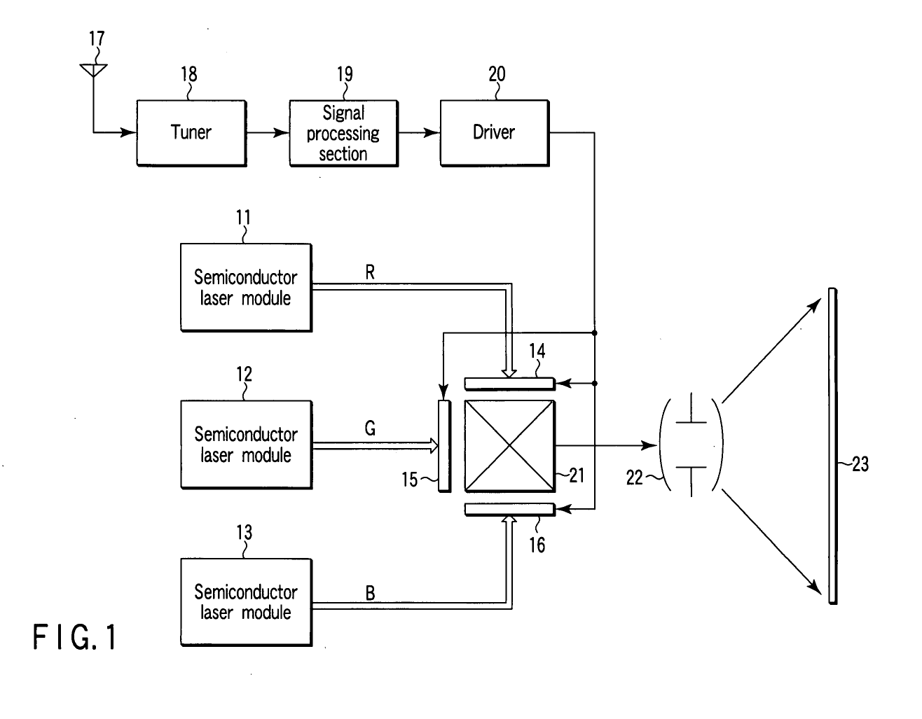

One embodiment of the present invention will be described below with reference to the accompanying drawings. FIG. 1 shows a video display apparatus described in the embodiment, that is, a liquid crystal projection TV (Television) receiver.

In FIG. 1, reference numerals 11 to 13 individually denote a semiconductor laser modules. The semiconductor laser modules 11 to 13 emit R (Red), G (Green) and B (Blue) laser beams, respectively.

R, G and B laser beams emitted from the semiconductor laser modules 11 to 13 are incident on spatial modulating means, that is, liquid crystal panels 14, 15 and 16, which are located correspondingly to each beam.

On the other hand, a tuner 18 selects a television broadcasting signal received by an antenna 17. Thereafter, a signal processing section 19 demodulates the received television-broadcasting signal so that the signal can be generated as a video signal. The video signal is inputted to liquid crystal panels 14 to 16 via a driver 20.

The R, G and B laser beams incident on liquid crystal panels 14 to 16 receive spatial demodulation by the video signal, and are synthesized by synthesizing means such as dichroic prism 21.

The beam thus synthesized is enlarged and projected on a screen 23 via a projection lens 22, and thereby, a television broadcasting video image is displayed thereon.

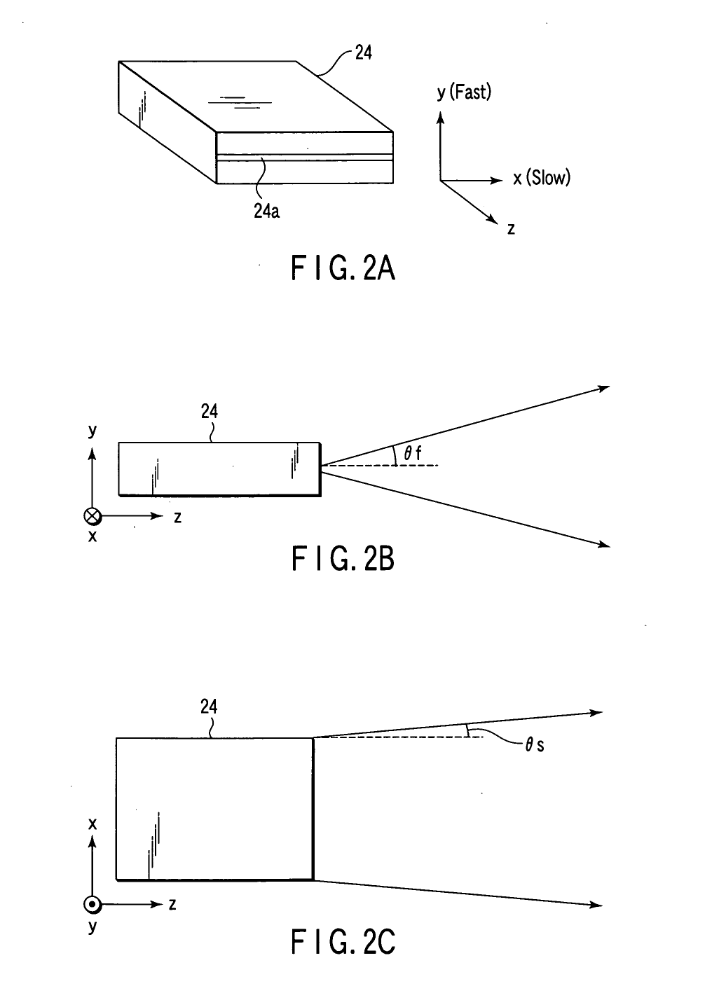

FIG. 2A shows the appearance of a semiconductor laser device 24 applied to the foregoing semiconductor laser modules 11 to 13. The semiconductor laser device 24 is formed into an approximately rectangular shape, and a beam emitting region, that is, a thin and long active layer 24a is exposed on one side used as the beam emitting end face.

Here, the direction perpendicular to the active layer 24a, that is, the shorter direction of the active layer 24a is defined as the fast axis (y axis) direction. The length of the fast axis direction of the active layer 24a is several μm.

The direction parallel to the active layer 24a, that is, the longer direction of the active layer 24a is defined as the slow axis (x axis) direction. The length of the slow axis direction of the active layer 24a is several 100 μm.

The traveling direction of the laser beam emitted from the active layer 24a, that is, the direction vertical to the beam emitting end face is defined as the z-axis direction.

As shown in FIG. 2B, the laser beam from the active layer 24a is emitted having a spread angle θf of ± several 10° in the fast axis direction. As illustrated in FIG. 2C, the laser beam from the active layer 24a is emitted having a spread angle θs of ± several degrees in the slow axis direction.

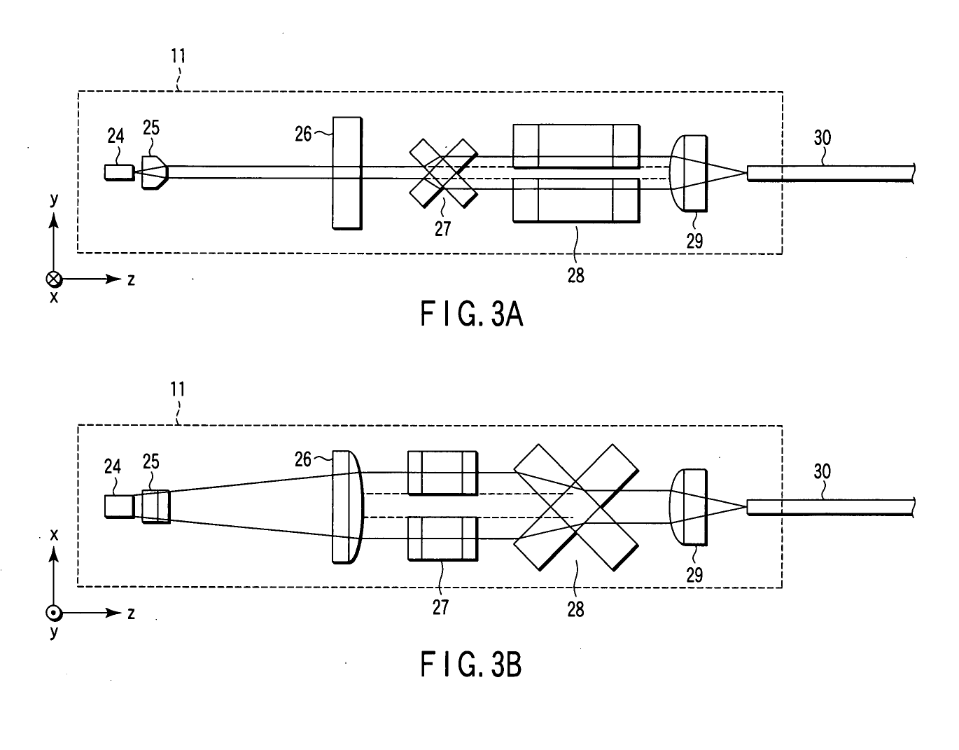

FIG. 3A and FIG. 3B are views to explain the structure of the semiconductor laser module 11 using the semiconductor laser device 24. Other semiconductor laser modules 12 and 13 have the same structure as the module 11 except that the color of the laser beam emitted from the semiconductor laser device 24 is different. Therefore, the details of the modules 12 and 13 are omitted.

FIG. 3A shows a state that the semiconductor laser module 11 is viewed in the slow axis direction, that is, the y-z plane. FIG. 3B shows a state that the semiconductor laser module 11 is viewed in the fast axis direction, that is, the x-z plane.

The laser beam emitted from the semiconductor laser device 24 is incident on a cylindrical lens 25 for fast-axis collimation so that it can be shaped into a beam parallel to the fast axis direction.

Thereafter, the laser beam emitted from the cylindrical lens 25 is incident on a cylindrical lens 26 for slow-axis collimation so that it can be shaped into a beam parallel to the slow axis direction.

The laser beam emitted from the cylindrical lens 26 is successively incident on first and second beam shaping sections 27 and 28, and shaped therein. Thereafter, the laser beam is collected by a collective lens 29, and thereafter, incident on the core of an optical fiber cable 30.

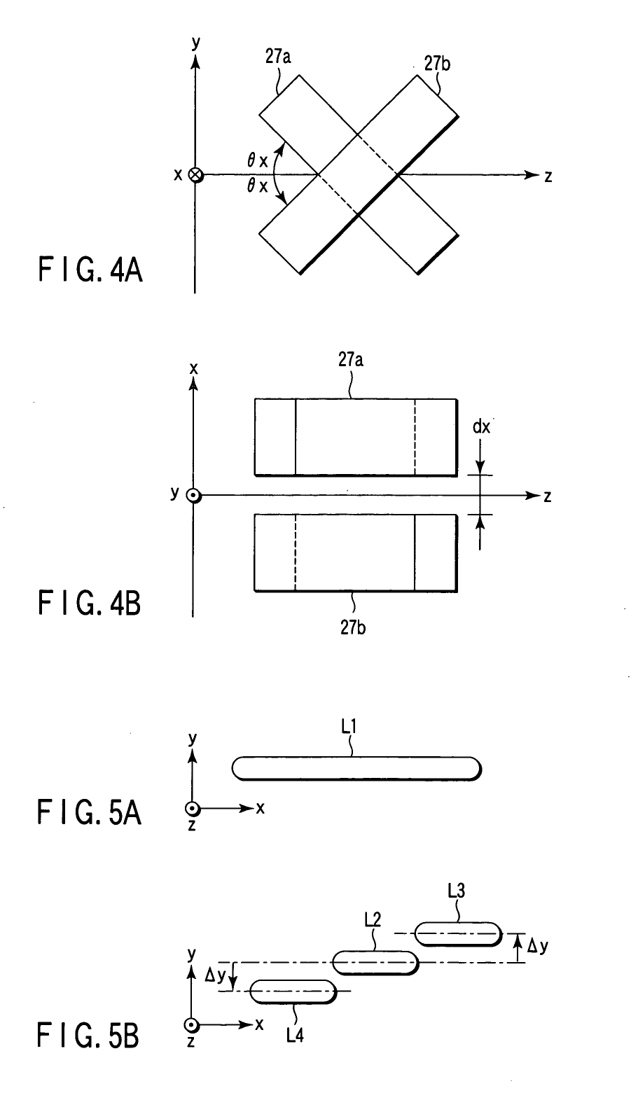

FIG. 4A and FIG. 4B show the structure of the first beam shaping section 27. FIG. 4A shows a state that the first beam shaping section 27 is viewed in the slow axis direction, that is, the y-z plane. FIG. 4B shows a state that the first beam shaping section 27 is viewed in the fast axis direction, that is, the x-z plane.

The first beam shaping section 27 is composed of two flat-shaped lenses 27a and 27b each having a predetermined thickness. The lenses 27a and 27b are located together in the slow axis direction in a state that their plane is oriented toward the direction facing the traveling direction of the laser beam.

In this case, the lenses 27a and 27b are arranged with a predetermined space dx in the slow axis direction. One lens 27a is inclined at only predetermined angle θx to the z-axis around the slow axis. The other lens 27b is inclined in the direction reverse to the lens 27a at only predetermined angle θx to the z-axis around the slow axis.

FIG. 5A shows a shape of a laser beam L1, which is incident on the first beam shaping section 27 after being emitted from the cylindrical lens 26. More specifically, the laser beam L1 has a thin and long shape, which is shorter in the fast axis direction while being longer in the slow axis direction.

When being incident on the first beam shaping section 27, the laser beam L1 having the foregoing shape is emitted in the following manner. As seen from FIG. 5B, the middle portion L2 of the laser beam L1 is intactly emitted through a space of the interval dx formed between lenses 27a and 27b.

One end portion L3 of the laser beam L1 is incident on the inclined flat-shaped lens 27a. Thereafter, the end portion L3 is emitted in a state of being shifted in parallel to the middle portion L2 by a predetermined distance Δy in the fast axis direction.

The other end portion L4 of the laser beam L1 is incident on the flat-shaped lens 27b inclined in the direction reverse to the lens 27a. Thereafter, the other end portion L4 is emitted in a state of being shifted in parallel to the middle portion L2 by a predetermined distance Ay in the direction reverse to the end portion L3 in the fast axis direction.

In other words, the first beam shaping section 27 has a function of dividing the laser beam L1 having a thin and long shape in the slow axis direction into three portions. The three portions are middle portion L2, end portions L3 and L4, which are shifted in parallel to the middle portion L2 by a predetermined distance Δy in the direction reverse to each other in the fast axis direction.

The refractive index, inclined angle and thickness of the lenses 27a and 27b are varied, and thereby, the parallel shift of the end portions L3 and L4 of the laser beam L1 is arbitrarily set. The ratio of dividing the laser beam L1 into three is arbitrarily set by varying the interval dx between lenses 27a and 27b.

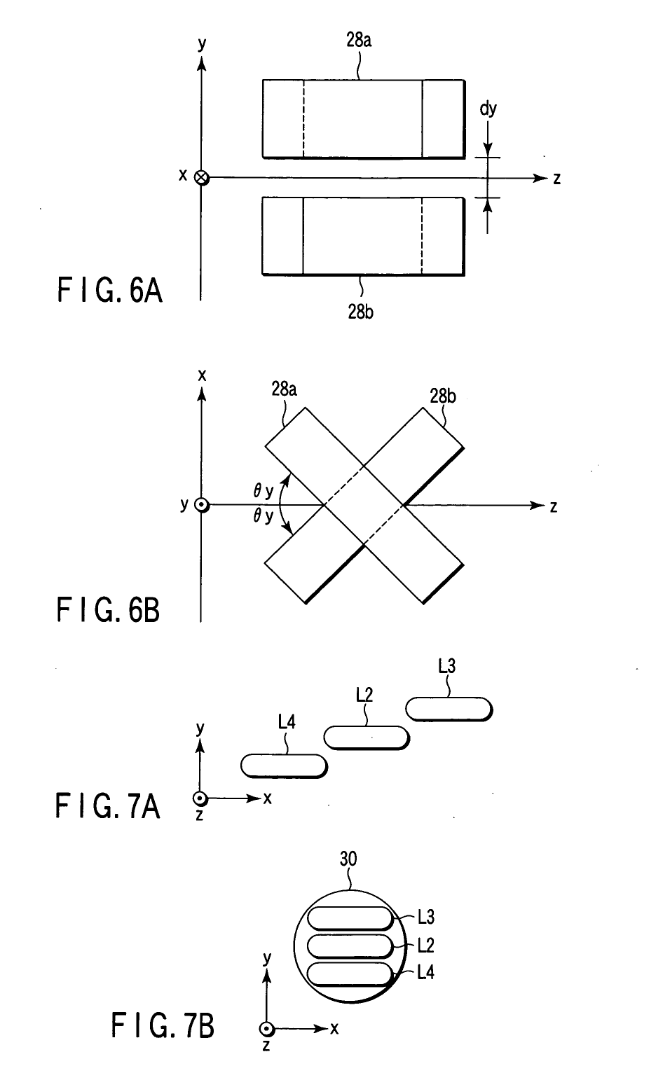

FIG. 6A and FIG. 6B show the structure of the second beam shaping section 28. FIG. 6A shows a state that the second beam shaping section 28 is viewed in the slow axis direction, that is, the y-z plane. FIG. 6B shows a state that the second beam shaping section 28 is viewed in the fast axis direction, that is, the x-z plane.

The second beam shaping section 28 is composed of two flat-shaped lenses 28a and 28b each having a predetermined thickness. The lenses 28a and 28b are located together in the fast axis direction in a state that their plane is oriented toward the direction facing the traveling direction of the laser beam.

In this case, the lenses 28a and 28b are arranged with a predetermined space dy in the fast axis direction. One lens 28a is inclined at only predetermined angle θy to the z-axis around the fast axis. The other lens 28b is inclined in the direction reverse to the lens 28a at only predetermined angle θy to the z-axis around the fast axis.

FIG. 7A shows each shape of laser beam L2, L3 and L4, which is incident on the second beam shaping section 28 after being emitted from the first beam shaping section 27. When the laser beams L2 to L4 are being incident on the second beam shaping section 28, the middle portion L2 is intactly emitted through a space of an interval dy formed between lenses 28a and 28b, as seen from FIG. 7B.

One end portion L3 of the laser beam is incident on the inclined flat-shaped lens 28a. Thereafter, the end portion L3 is emitted in a state of being shifted in parallel to the middle portion L2 by a predetermined distance in the slow axis direction.

The other end portion L4 of the laser beam is incident on the flat-shaped lens 28b inclined in the direction reverse to the lens 28a. Thereafter, the other end portion L4 is emitted in a state of being shifted in parallel toward the middle portion L2 by a predetermined distance in the slow axis direction.

In this case, laser beams L3 and L4 are shifted in parallel that they come into line with the laser beam L2 on the fast axis. In other words, the second beam shaping section 28 has the following function. Laser beams L3 and L4 shifted in parallel to the fast axis direction in the first beam shaping section 27 is shifted in parallel so that they can be arranged in ling via the middle portion L2 in the fast axis direction.

The refractive index, inclined angle and thickness of the lenses 27a and 27b are varied, and thereby, parallel shifting of the laser beams L3 and L4 in the slow axis is arbitrarily set.

According to the embodiment, the laser beam emitted from the semiconductor laser device 24 is shaped into a parallel beam, that is, laser beam L1 having the thin and long shape by cylindrical lenses 25 and 26. The laser beam L1 is divided into three in the longitudinal direction, and thereafter, divided three portions are shifted so that they can be arranged in line along the fast axis.

Therefore, divided laser beams L2 to L4 are all incident on the circular core of the optical fiber cable 30 without generating wasteful beam space. As a result, the laser beam emitted from the semiconductor laser device 24 can be incident on the optical fiber cable 30 with high efficiency and high optical density.

In other words, the laser beam emitted from the semiconductor laser device 24 has an area, which is not optically coupled with the optical fiber cable 30 because the effective numerical aperture of the slow axis exceeds that of the optical fiber cable. For this reason, the foregoing area of the laser beam is shifted in the fast axis having larger numerical aperture. By doing so, the laser beam can be optically coupled with the optical fiber cable 30 with high efficiency and high optical density.

The first and second beam shaping sections 27 and 28 are composed of two flat-shaped lenses 27a; 27b and 28a; 28b, respectively. Thus, the structure can be simplified without using lenses having special shape.

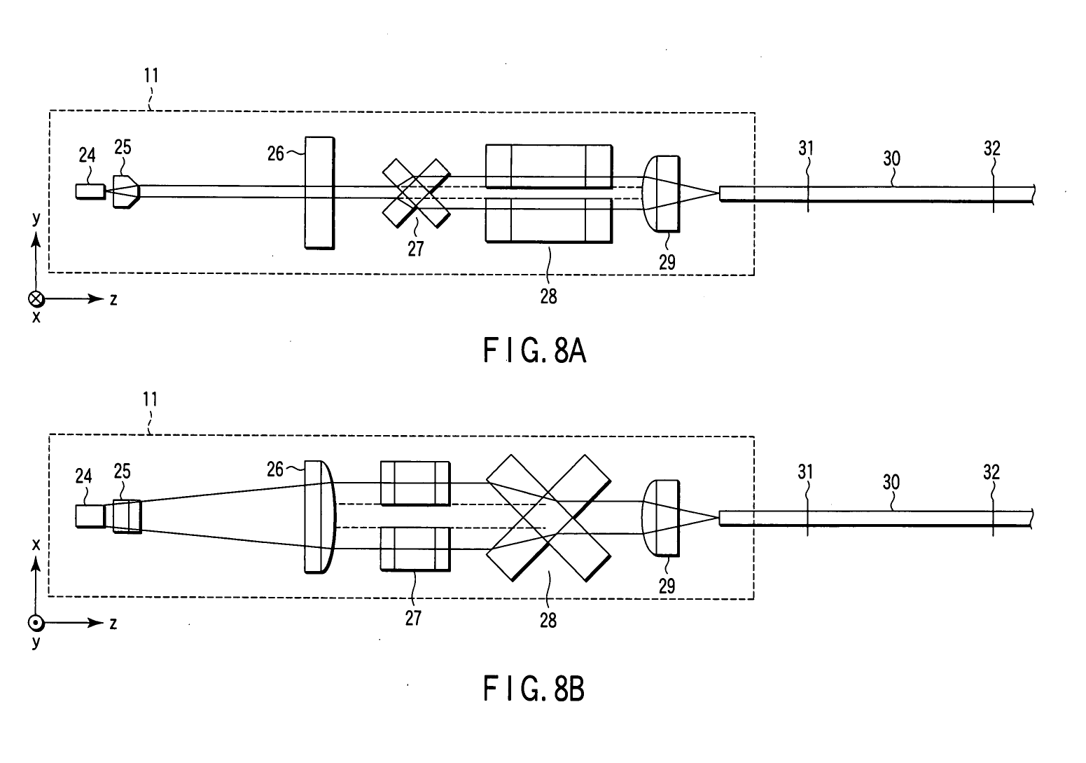

FIG. 8A and FIG. 8B show a modification example of the foregoing embodiment. In FIG. 8A and FIG. 8B, the same reference numerals are used to designate the components identical to FIG. 3A and FIG. 3B. Laser active substance is added to the core of the optical fiber cable 30.

The optical fiber cable 30 is provided with reflecting devices 31 and 32. The reflecting device 31 transmits excitation light emitted from the semiconductor laser device 24, and reflects laser beam generated in the optical fiber cable 30. The reflecting device 32 partially reflects the laser beam generated in the optical fiber cable 30.

For example the following condition is given. More specifically, the semiconductor laser wavelength ranges from 830 to 850 nm, and the laser active substance added to the core of the optical fiber cable 20 is Pr³⁺/Yb³⁺. In this case, the reflecting device 31 totally transmits the wavelength ranging 830 to 850 nm while totally reflecting the wavelength of 635 nm. On the other hand, the reflecting device 32 partially reflects the wavelength of 635 nm.

The excitation light incident on the optical fiber cable 30 is absorbed into the laser active substance; therefore, light having a wavelength of is generated. The generated light having 635 nm is generated as laser beam of 635 nm by a resonator composed of reflecting devices 31 and 32, and thereafter, outputted from the reflecting device 32.

In this case, since high power and high density excitation light is required, it is specially effective to use the semiconductor laser module 11 shown in FIG. 3A and FIG. 3B.

The present invention is not limited to the embodiments described above, and various modifications of components may be made without departing from the spirit or scope of the general inventive concept. Several components disclosed in the foregoing embodiments are properly combined, and thereby, various inventions may be made. For example, some components may be deleted from all components shown in the embodiments. Components according to different embodiment may be properly combined.

1. A semiconductor laser module comprising:
a semiconductor laser device;
a collimating section collimating a laser beam emitted from the semiconductor laser device;
a beam shaping section parallel-shifting at least part of a laser beam emitted from the collimating section to a position satisfying an effective numerical aperture of the optical fiber cable when the laser beam exceeds the effective numerical aperture of the optical fiber cable; and
a collecting section collecting a laser beam emitted from the beam shaping section onto a light incident end face of the optical fiber cable.

2. The module according to claim 1, wherein the beam shaping section does not parallel-shift the laser beam emitted from the collimating section, that is, a portion satisfying the effective numerical aperture of the optical fiber cable, while parallel-shifting a portion exceeding the effective numerical aperture to a position satisfying the effective numerical aperture thereof.

3. The module according to claim 1, wherein the beam shaping section includes:
a first beam shaping section shifting at least part of the laser beam from the collimating section in parallel to a first direction; and
a second beam shaping section shifting laser beam parallel-shifted by the first beam shaping section to a second direction perpendicular to the first direction.

4. The module according to claim 1, wherein the beam shaping section shifts the laser beam from the collimating section in parallel using flat-shaped lenses, which are located in a state of being inclined at a predetermined angle so that their plane face each other toward the traveling direction of the laser beam from the collimating section.

5. The module according to claim 1, wherein the semiconductor laser device has a light emitting region having a slow axis direction longer than a fast axis direction, and emits a laser beam having a predetermined spread angle in each of fast and slow axis directions,
the collimating section collimates the laser beam emitted from the semiconductor laser device to each of fast and slow axis directions to shape a laser beam having the slow axis direction longer the fast axis direction, and
the beam shaping section parallel-shifts part of the laser beam emitted from the collimating section in the slow axis direction to a position satisfying the effective numerical aperture of the optical fiber cable.

6. The module according to claim 5, wherein the beam shaping section includes:
a first beam shaping section shifting part of the laser beam from the collimating section in the fast axis direction, said part of the laser beam being determined in the slow axis direction; and
a second beam shaping section parallel-shifting a laser beam parallel-shifted by the first beam shaping section in the slow axis direction so that the laser beam can be arranged in line in the fast axis direction with a laser beam, which is not parallel-shifted by the first beam shaping section.

7. The module according to claim 6, wherein the first beam shaping section parallel-shifts both end portions of the laser beam emitted from the collimating section in the slow axis direction to the direction reverse to each other along the fast axis direction, and
the second beam shaping section parallel-shifts each laser beam parallel-shifted by the first beam shaping section in the slow axis direction so that the laser beam can be arranged in line in the fast axis direction with a laser beam, which is not parallel-shifted by the first beam shaping section.

8. The module according to claim 6, wherein the first beam shaping section includes first and second flat-shaped lenses, which are located in a state of being inclined at an angle reverse to each other around the slow axis so that their planes face each other toward the traveling direction of the laser beam from the collimating section with respect to both end portions of the laser beam from the collimating section excluding the middle portion in the slow axis direction, and
the second beam shaping section includes third and fourth flat-shaped lenses, which are located in a state of being inclined at an angle reverse to each other around the fast axis so that their planes face each other toward the traveling direction of each laser beam emitted from the first and second lenses constituting the first beam shaping section and incident laser beams are arranged in line in the fast axis direction.

9. The module according to claim 1, wherein the optical fiber cable has a core to which laser active substance is added, and is formed with a resonator, which is composed of a first reflecting device transmitting a first wavelength light and reflecting a second wavelength light and a second reflecting device partially reflecting the second wavelength light.

10. A method of controlling a semiconductor laser beam, comprising:
collimating a laser beam emitted from the semiconductor laser device;
parallel-shifting at least part of the laser beam to a position satisfying an effective numerical aperture of the optical fiber cable when the collimated laser beam exceeds the effective numerical aperture of the optical fiber cable; and
collecting the collimated laser beam including the parallel-shifted laser beam onto a light incident end face of the optical fiber cable.

11. The method according to claim 10, wherein parallel-shifting the laser beam is not to parallel-shift the laser beam emitted from the collimating section, that is, a portion satisfying the effective numerical aperture of the optical fiber cable, while to parallel-shift a portion exceeding the effective numerical aperture to a position satisfying the effective numerical aperture thereof.

12. A video display apparatus comprising:
a semiconductor laser module parallel-shifting at least part of a laser beam collimated after being emitted from the semiconductor laser module to a position satisfying an effective numerical aperture of the optical fiber cable when the laser beam exceeds the effective numerical aperture of the optical fiber cable;
a modulating section spatially modulating a laser beam outputted from the semiconductor laser module via the optical fiber cable based on a video signal; and
a display section projecting and displaying optical output obtained from the modulating section on a screen.

13. The apparatus according to claim 12, wherein the semiconductor laser module and the modulating section are located correspondingly to each of R, G and B laser beams, and the display section synthesizes the optical output from each modulating section corresponding to R, G and B lights, and thereafter, projects it on the screen.
